(19) United States
(12) Patent Application Publication
(10) Pub. No.: US 2023/0352227 A1
(43) Pub. Date: Nov. 2, 2023

(54) ELECTRONIC COMPONENT, METHOD OF MANUFACTURING ELECTRONIC COMPONENT, FILTER MODULE, AND ELECTRONIC DEVICE

(71) Applicant: Murata Manufacturing Co., Ltd., Nagaokakyo-shi (JP)

(72) Inventors: Tomoyoshi HIEI, Nagaokakyo-shi (JP); Kentaro MIKAWA, Nagaokakyo-shi (JP)

(21) Appl. No.: 18/220,894

(22) Filed: Jul. 12, 2023

Related U.S. Application Data
(63) Continuation of application No. PCT/JP2022/003666, filed on Jan. 31, 2022.

(30) Foreign Application Priority Data
Feb. 5, 2021 (JP) 2021-017228

(51) Int. Cl. H01F 17/00; H01G 4/005; H03H 7/09

(52) U.S. Cl. CPC H01F 17/0013; H01G 4/005; H03H 7/09; H01F 2017/0073

(57) ABSTRACT

An electronic component includes a first insulator layer including thereon a first conductor pattern to define an inductor and a first electrode pattern to define a capacitor, and a second insulator layer including thereon a second conductor pattern to define the inductor and a second electrode pattern to define the capacitor. The first and second electrode patterns face each other across the second insulator layer to define the capacitor, and the second conductor pattern is electrically connected to the first conductor pattern along the first conductor pattern.

### CROSS REFERENCE TO RELATED APPLICATIONS

This application claims the benefit of priority to Japanese Patent Application No. 2021-017228 filed on Feb. 5, 2021 and is a Continuation Application of PCT Application No. PCT/JP2022/003666 filed on Jan. 31, 2022. The entire contents of each application are hereby incorporated herein by reference.

### BACKGROUND OF THE INVENTION

### 1. Field of the Invention

The present invention relates to an electronic component including an inductor and a capacitor, a method of manufacturing an electronic component, a filter module including an electronic component, and an electronic device including a filter module.

### 2. Description of the Related Art

In the electronic component in Japanese Unexamined Patent Application Publication No. 2019-186696, a conductor layer for forming an inductor and a conductor layer for forming a capacitor are formed on a single layer. In addition, in the electronic component in Japanese Unexamined Patent Application Publication No. 2019-186696, conductor layers for forming an inductor formed on different layers are connected in parallel to each other.

### SUMMARY OF THE INVENTION

In a structure that improves the Q values of inductors by connecting the inductors in parallel to each other as in the electronic component described in Japanese Unexamined Patent Application Publication No. 2019-186696, the volumetric efficiency of the inductors is low. Accordingly, to obtain inductors with high Q values, the size of the electronic component is increased, and in an electronic component having a limited external size, the effect of improving the Q values of the inductors is low.

Accordingly, preferred embodiments of the present invention provide electronic components each having a small size but also including a capacitor and an inductor with a high Q value. Preferred embodiments of the present invention also provide methods of manufacturing electronic components, filter modules including electronic components, and electronic devices including filter modules.

An electronic component according to an aspect of a preferred embodiment of the present disclosure includes a first insulator layer including thereon a first conductor pattern to define an inductor and a first electrode pattern to define a capacitor, and a second insulator layer including thereon a second conductor pattern to define the inductor and a second electrode pattern to define the capacitor. In addition, the first electrode pattern and the second electrode patter face each other across the second insulator layer to define the capacitor, and the second conductor pattern is electrically connected to the first conductor pattern along the first conductor pattern.

In the structure described above, since the second conductor pattern is electrically connected to the first conductor pattern along the first conductor pattern, the occupancy rate of the conductors of the inductor per unit volume is high. Accordingly, an inductor having a high Q value is obtained. In addition, since the first electrode pattern and the second electrode pattern defining the capacitor face each other across a single insulator layer, the occupancy rate of the electrodes of the capacitor obtained per unit volume does not decrease.

A method of manufacturing an electronic component according to an aspect of a preferred embodiment of the present invention includes simultaneously forming a first conductor pattern for forming an inductor and a first electrode pattern for forming a capacitor on a first insulator layer, forming a second insulator layer on a surface of the first insulator layer on which the first conductor pattern was formed, the second insulator layer including a cavity above the first conductor pattern, and forming a second conductor pattern for forming the inductor in the cavity and on the second insulator layer and forming a second electrode pattern for forming the capacitor at a position facing the first electrode pattern across the second insulator layer.

Since the manufacturing method can simultaneously form the second electrode pattern and the second conductor pattern on the second insulator layer and in the cavity, the electronic component can manufacture with a small number of steps.

A filter module according to an aspect of a preferred embodiment of the present disclosure includes the electronic component according to a preferred embodiment of the present invention, and an inductor or a capacitor connected to the inductor or the capacitor of the electronic component.

An electronic device according to an aspect of a preferred embodiment of the present disclosure includes an electronic component according to a preferred embodiment of the present invention or a filter module according to a preferred embodiment of the present invention.

According to preferred embodiments of the present invention, it is possible to obtain electronic components that are each small but including a capacitor and an inductor with a high Q value, methods of manufacturing electronic components, filter modules including electronic components, and electronic devices including filter modules.

The above and other elements, features, steps, characteristics and advantages of the present invention will become more apparent from the following detailed description of the preferred embodiments with reference to the attached drawings.

### BRIEF DESCRIPTION OF THE DRAWINGS

FIG. 1 illustrates exploded plan views of an electronic component 11 according to a first preferred embodiment of the present invention.

FIG. 2A is a plan view of the electronic component 11, FIG. 2B is a sectional view taken along line X-X in FIG. 2A, and FIG. 2C is a sectional view taken along line Y-Y in FIG. 2A.

FIG. 3 is a circuit diagram of the electronic component 11.

FIG. 4 is a circuit diagram of a filter module according to the first preferred embodiment of the present invention.

FIGS. 5A to 5C are sectional views of individual stages in the step of forming a first conductor pattern and a first electrode pattern.

FIGS. 6A to 6C are sectional views of individual stages in the step of forming a second insulator layer S2.

FIGS. 7A to 7D are sectional views of individual stages in the step of forming the first conductor pattern, a second conductor pattern, the first electrode pattern, a second electrode pattern, and a third insulator layer.

FIGS. 8A to 8C are sectional views of the electronic component in which the line widths of a first conductor pattern CL11 and a second conductor pattern CL12 are identical to each other.

FIGS. 9A and 9B are sectional view illustrating examples of the positional relationship between the first conductor pattern CL11 and the second conductor pattern CL12.

FIG. 10 illustrates exploded plan views of an electronic component 12A according to a second preferred embodiment of the present invention.

FIG. 11A is a plan view of the electronic component 12A, and FIG. 11B is a sectional view taken along line X-X in FIG. 11A.

FIG. 12 illustrates exploded plan views of another electronic component 12B according to the second preferred embodiment of the present invention.

FIG. 13A is a plan view of the electronic component 12B, and FIG. 13B is a sectional view taken along line X-X in FIG. 13A.

FIG. 14 is a perspective view of a filter module 13 according to a third preferred embodiment of the present invention.

FIG. 15 illustrates exploded plan views of insulator layers of the filter module 13 and conductor patterns formed on the insulator layers.

FIG. 16 is a circuit diagram of the filter module 13.

FIG. 17 illustrates exploded plan views of insulator layers of another filter module according to the third preferred embodiment of the present invention and conductor patterns formed on the insulator layers.

FIG. 18 illustrates exploded plan views of insulator layers of another filter module according to the third preferred embodiment of the present invention and conductor patterns formed on the insulator layers.

FIGS. 19A to 19E are diagrams schematically illustrating the junction structure of a plurality of conductor patterns for forming an inductor and a via conductor V.

FIG. 20 is a block diagram illustrating the structure of an electronic device 201 according to a fifth preferred embodiment of the present invention.

### DETAILED DESCRIPTION OF THE PREFERRED EMBODIMENTS

A plurality of preferred embodiments of the present invention will be described below with several specific examples with reference to the drawings. In the drawings, the same components are denoted by the same reference numerals. For ease of the description or understanding of the main points, a plurality of preferred embodiments will be described for convenience of description, but partial replacement or combinations of the structures illustrated in different preferred embodiments is possible. In the second and subsequent preferred embodiments, the descriptions of matters that are identical to those in the first preferred embodiment will be omitted, and only the differences will be described. In particular, the same operation and effect due to the same structure are not described for each of the preferred embodiments.

### First Preferred Embodiment

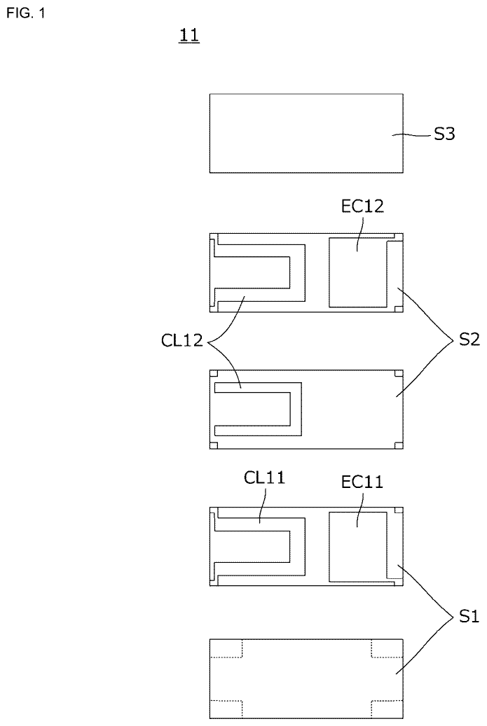

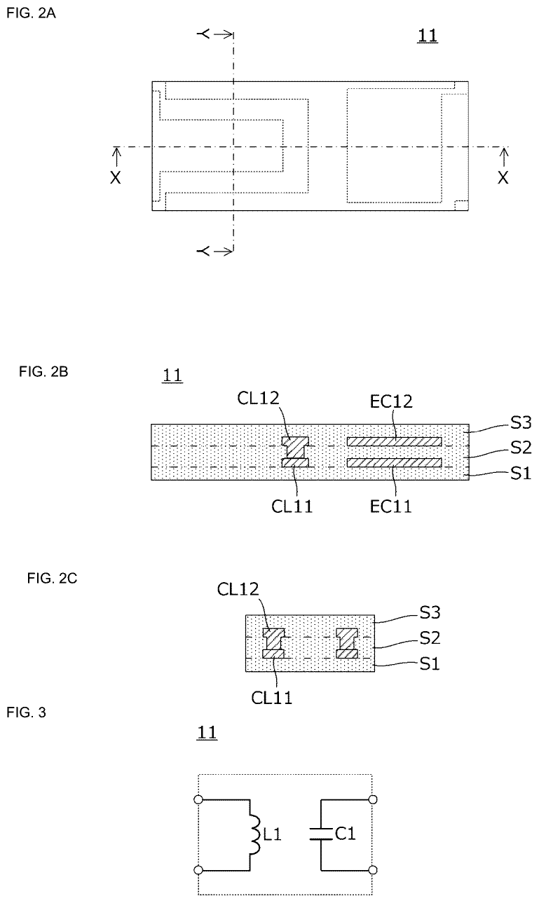

FIG. 1 illustrates exploded plan views of an electronic component 11 according to the first preferred embodiment. FIG. 2A is a plan view of the electronic component 11, FIG. 2B is a sectional view taken along line X-X in FIG. 2A, and FIG. 2C is a sectional view taken along line Y-Y in FIG. 2A.

This electronic component 11 includes a first insulator layer S1, a second insulator layer S2, and a third insulator layer S3. A terminal electrode is formed on the lower surface of the first insulator layer S1. A first conductor pattern CL11 for forming an inductor and a first electrode pattern EC11 for forming a capacitor are formed on the upper surface of the first insulator layer S1. A second conductor pattern CL12 for forming the inductor and a second electrode pattern EC12 for forming the capacitor are formed on the upper surface of the second insulator layer S2. The second conductor pattern CL12 is also formed in the second insulator layer S2. That is, the second conductor pattern CL12 includes a portion formed on the upper surface of the second insulator layer S2 and a portion formed in the second insulator layer S2. A third insulator layer S3 that covers the second insulator layer S2, the second conductor pattern CL12, and the second electrode pattern EC12 is formed on the upper surface of the second insulator layer S2.

The first electrode pattern EC11 and the second electrode pattern EC12 face each other across the second insulator layer S2. In this structure, the first electrode pattern EC11, the second electrode pattern EC12, and the second insulator layer S2 define the capacitor.

The second conductor pattern CL12 formed on the second insulator layer S2 has a shape that is continuous along the first conductor pattern CL11. In the present preferred embodiment, the second conductor pattern CL12 is electrically connected to the first conductor pattern CL11 in the thickness direction of the second insulator layer S2 over the entire length of extension (see FIGS. 2B and 2C). In other words, a second conductor pattern CL12 portion formed in the second insulator layer S2 is connected to the first conductor pattern CL11 over the entire length of extension of the second conductor pattern CL12 in plan view. In this structure, the first conductor pattern CL11 and the second conductor pattern CL12 define the inductor. The first conductor pattern CL11 and the second conductor pattern CL12 are formed so as to be electrically connected to each other in the thickness direction of the second insulator layer S2 as described above, and accordingly, the thickness of the electrodes of the inductor can be increased. This can increase the surface areas of the electrodes, reduce an increase in high-frequency resistance due to the skin effect or the like when a high-frequency signal propagates through the electrodes of the inductor, and increase the Q value of the inductor. It should be noted that the first conductor pattern CL11 and the second conductor pattern CL12 are electrically connected to each other over substantially the entire length of extension of these patterns in plan view in the present preferred embodiment, but at least some portions thereof need only be electrically connected to each other.

FIG. 3 is a circuit diagram of the electronic component 11. This electronic component 11 includes an inductor L1 and a capacitor C1.

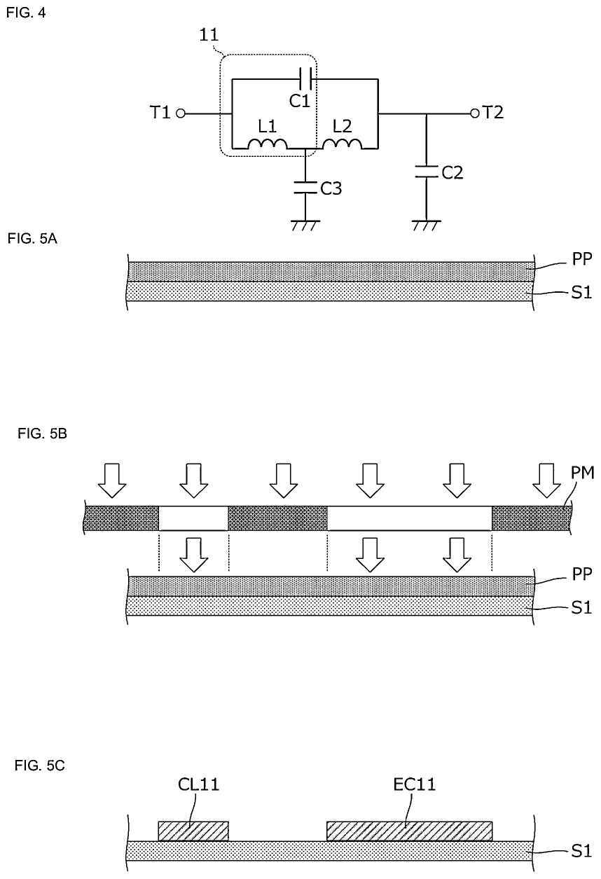

FIG. 4 is a circuit diagram of a filter module according to the first preferred embodiment. This filter module includes terminals T1 and T2 that define an input/output port with respect to the ground. The filter circuit unit includes the inductors L1, an inductor L2, the capacitor C1, a capacitor C2, and a capacitor C3.

As described above, the filter module can be formed by including the electronic component illustrated in FIGS. 1 to 3 and the inductor L2 or the capacitors C2 and C3 connected to the inductor L1 or the capacitor C1 of the electronic component. The inductor L2 and the capacitors C2 and C3 can be formed similarly in the plurality of insulator layers in which the inductor L1 and the capacitor C1 are formed.

Next, a non-limiting example of a method of manufacturing the electronic component 11 will be explained. FIGS. 5A to 5C are sectional views of individual stages in the step of forming the first conductor pattern and the first electrode pattern.

First, as illustrated in FIG. 5A, a photosensitive conductive paste is applied onto the upper surface of the first insulator layer S1 by screen printing and dried to form a film PP of the photosensitive conductive paste.

Next, as illustrated in FIG. 5B, the film PP of the photosensitive conductive paste is irradiated with UV light via a photomask PM.

After that, the film PP of the photosensitive conductive paste is developed and sintered to form the first conductor pattern CL11 and the first electrode pattern EC11 as illustrated in FIG. 5C.

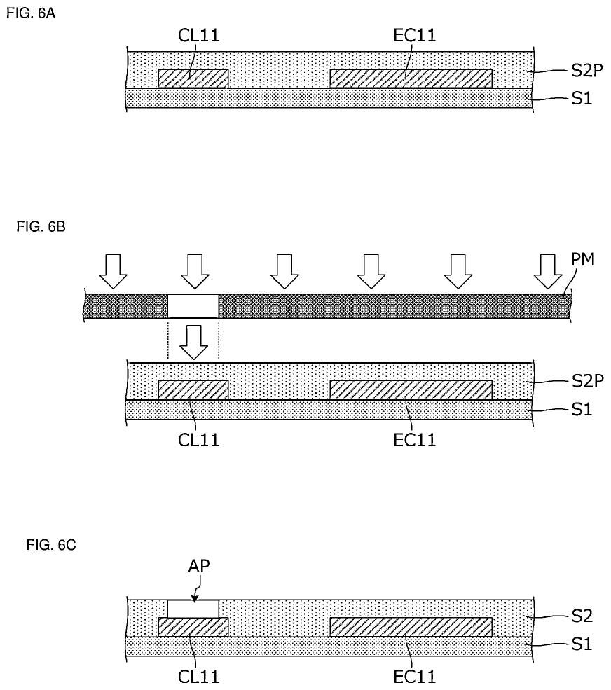

FIGS. 6A to 6C are sectional views of individual stages in the step of forming a second insulator layer S2.

First, as illustrated in FIG. 6A, a photosensitive insulating paste is applied onto the upper surface of the first insulator layer S1 by screen printing and dried to form a film S2P of the photosensitive insulating paste.

Next, as illustrated in FIG. 6B, the film S2P of the photosensitive insulating paste is irradiated with UV light via the photomask PM.

After that, the film S2P of the photosensitive insulating paste is developed and sintered to form a second insulator layer S2 including a cavity AP, as illustrated in FIG. 6C.

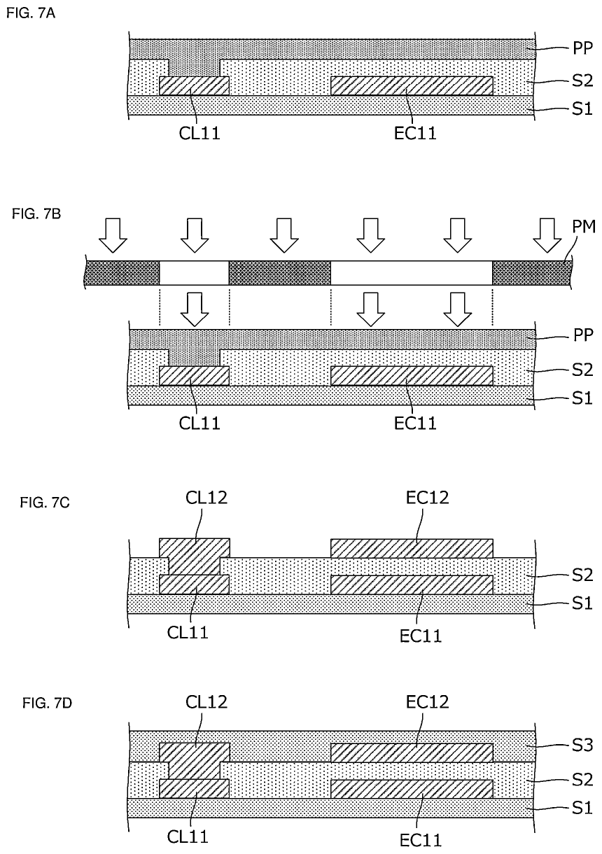

FIGS. 7A to 7D are sectional views of individual stages in the step of forming the first conductor pattern, the second conductor pattern, the first electrode pattern, the second electrode pattern, and the third insulator layer.

First, as illustrated in FIG. 7A, a photosensitive conductive paste is applied onto the upper surface of the second insulator layer S2 by screen printing and dried to form the film PP of the photosensitive conductive paste.

Next, as illustrated in FIG. 7B, the film PP of the photosensitive conductive paste is irradiated with UV light via the photomask PM.

After that, the film PP of the photosensitive conductive paste is developed and sintered to form the second conductor pattern CL12 and the second electrode pattern EC12 as illustrated in FIG. 7C.

Finally, as illustrated in FIG. 7D, the third insulator layer S3 is formed on the upper surface of the second insulator layer S2.

Since the method of manufacturing the electronic component illustrated above can form the second electrode pattern EC12 and the second conductor pattern CL12 simultaneously on the second insulator layer S2 and in the cavity AP, the electronic component can be manufactured in a small number of steps.

Although the manufacturing method that uses a photomask is described above, methods of manufacturing electronic components according to preferred embodiments of the present invention are not limited to this manufacturing method. For example, the electronic component may be manufactured by a method of laminating insulating sheets by applying a step of forming an electrode pattern by screen printing or a step of filling a hole of an insulating layer created by a laser with a via electrode.

Next, several modifications of overlapping of the first conductor pattern CL11 and the second conductor pattern CL12 will be described.

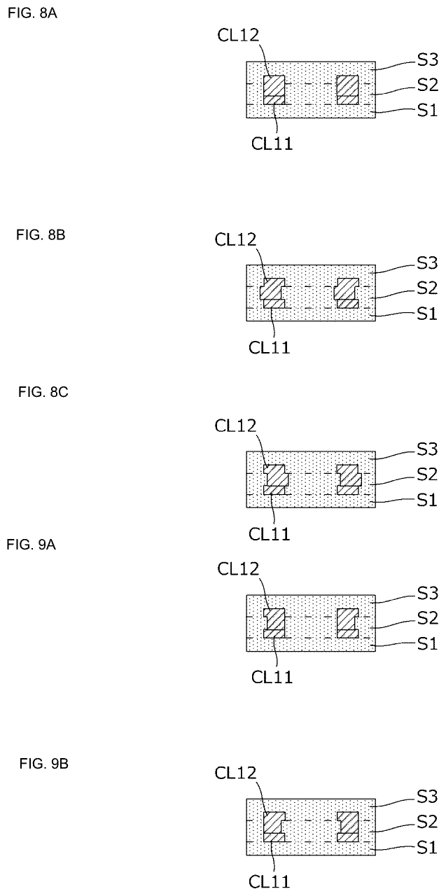

FIGS. 8A to 8C are sectional views of the electronic component in which the line widths of the first conductor pattern CL11 and the second conductor pattern CL12 are identical to each other. These sectional positions are the same as the sectional positions illustrated in FIG. 2C. As illustrated in FIG. 8A, preferably, the first conductor pattern CL11 and the second conductor pattern CL12 have an equal line width and entirely overlap each other in plan view. However, depending on the formation accuracy of the conductor patterns of each of the layers, the line width of the second conductor pattern CL12 projects beyond the line width of the first conductor pattern CL11 as illustrated in FIGS. 8B and 8C. As described above, when the conductor patterns project outward or are recessed inward at the inner edge and the outer edge of the loop, the current density becomes non-uniform, and conductor loss increases in places in which the current density is high.

On the other hand, in the example illustrated in FIGS. 2B and 2C, each of the first conductor pattern CL11 and the second conductor pattern CL12 has a loop shape or a shape that forms a portion of a loop and, in plan view in the lamination direction of the first conductor pattern CL11 and the second conductor pattern CL12, a conductor pattern of the second conductor pattern CL12 that is formed in the second insulator layer S2 is located on the inner side of the line width (both ends in the width direction) formed on the upper surface of the second insulator layer S2 of the second conductor pattern CL12 and the line width (both ends in the width direction) of the first conductor pattern CL11. As described above, the line width of the conductor pattern of the second conductor pattern CL12 that is formed in the second insulator layer S2 is determined to be smaller than the line width of the conductor pattern of the second conductor pattern CL12 formed on the upper surface of the second insulator layer S2 and the line width of the first conductor pattern CL11. This can prevent the conductor pattern formed in the second insulator layer S2 of the second conductor pattern CL12 from projecting toward the opening of the loop.

FIGS. 9A and 9B are sectional views illustrating examples of the positional relationship between the first conductor pattern CL11 and the second conductor pattern CL12. These sectional positions are the same as the sectional positions illustrated in FIG. 2C.

In any of the electronic components illustrated in FIGS. 9A and 9B, the line width of the conductor pattern of the second conductor pattern CL12 formed in the second insulator layer S2 is smaller than the line width of the conductor pattern of the second conductor pattern CL12 that is formed on the upper surface of the second insulator layer S2 and the line width of the first conductor pattern CL11. In the example illustrated in FIG. 9A, the inner edge of the loop of the first conductor pattern CL11 and the inner edge of the loop of second conductor pattern CL12 are present at the same position in plan view in the lamination direction of the first conductor pattern CL11 and the second conductor pattern CL12. That is, the inner periphery of the first conductor pattern CL11 is aligned with the inner periphery of the second conductor pattern CL12. In the example illustrated in FIG. 9B, the outer edge of the loop of the first conductor pattern CL11 and the outer edge of the loop of the second conductor pattern CL12 are present at the same position in plan view. That is, the outer periphery of the first conductor pattern CL11 is aligned with the outer periphery of the second conductor pattern CL12.

The inner peripheral portions of the first conductor pattern CL11 and the second conductor pattern CL12 that define the inductor have a higher current density due to proximity effects. Accordingly, as illustrated in FIG. 9A, it is preferable that the amount of projection of the conductor patterns CL11 and CL12 toward the opening of the loops is small.

### Second Preferred Embodiment

In a second preferred embodiment, an example of an electronic component including the plurality of first conductor patterns, a plurality of second conductor patterns, and three or more first electrode patterns or second electrode patterns will be described.

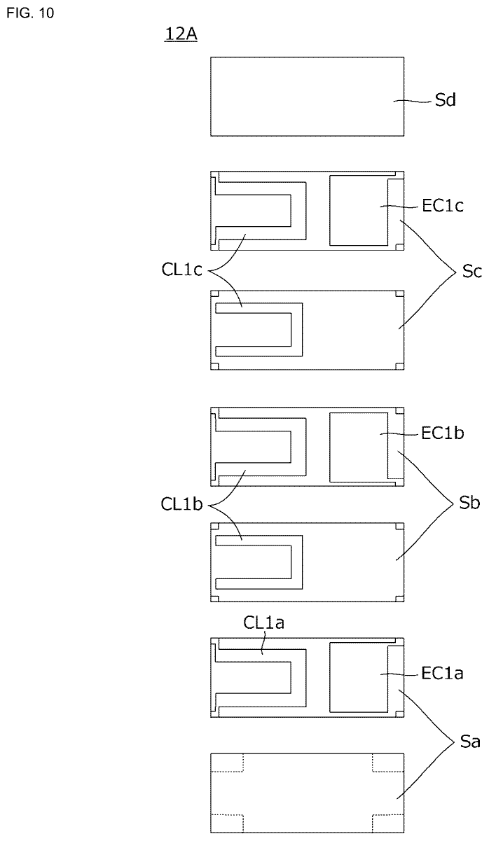

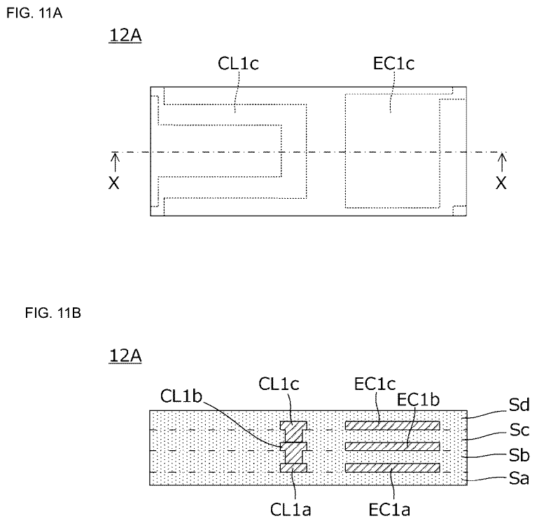

FIG. 10 illustrates exploded plan views of an electronic component 12A according to the second preferred embodiment. FIG. 11A is a plan view of the electronic component 12A, and FIG. 11B is a sectional view taken along line X-X in FIG. 11A.

This electronic component 12A includes insulator layers Sa, Sb, Sc, and Sd. A terminal electrode is formed on the lower surface of the insulator layer Sa. A conductor pattern CL1a and an electrode pattern EC1a are formed on the upper surface of the insulator layer Sa. A conductor pattern CL1b and an electrode pattern EC1b are formed on the upper surface of the insulator layer Sb. The conductor pattern CL1b is also formed in the insulator layer Sb. That is, the conductor pattern CL1b includes a portion formed on the upper surface of the insulator layer Sb and a portion formed in the insulator layer Sb. A conductor pattern CL1c and an electrode pattern EC1c are formed on the upper surface of the insulator layer Sc. The conductor pattern CL1c is also formed in the insulator layer Sc. That is, the conductor pattern CL1c includes a portion formed on the upper surface of the insulator layer Sc and a portion formed in the insulator layer Sc. The insulator layer Sd that covers the insulator layer Sc, the conductor pattern CL1c, and the electrode pattern EC1c is formed on the upper surface of the insulator layer Sc.

This electronic component 12A includes the insulator layers Sa, Sb, Sc, and Sd. A terminal electrode is formed on the lower surface of the insulator layer Sa. The conductor pattern CL1a and the electrode pattern EC1a are formed on the upper surface of the insulator layer Sa. The conductor pattern CL1b and the electrode pattern EC1b are formed on the upper surface of the insulator layer Sb. The conductor pattern CL1c is formed in the insulator layer Sb. The conductor pattern CL1c and the electrode pattern EC1c are formed on the upper surface of the insulator layer Sc. The conductor pattern CL1c is formed in the insulator layer Sc. The insulator layer Sd that covers the insulator layer Sc, the conductor pattern CL1c, and the electrode pattern EC1c is formed on the upper surface of the insulator layer Sc.

In the pair of conductor patterns CL1a and CL1b, the conductor pattern CL1a corresponds to the first conductor pattern, the conductor pattern CL1b corresponds to the second conductor pattern, the insulator layer Sa corresponds to the first insulator layer, the insulator layer Sb corresponds to the second insulator layer, and the insulator layer Sc corresponds to the third insulator layer. In addition, in the pair of conductor patterns CL1b and CL1c, the conductor pattern CL1b corresponds to the first conductor pattern, the conductor pattern CL1c corresponds to the second conductor pattern, the insulator layer Sb corresponds to the first insulator layer, the insulator layer Sc corresponds to the second insulator layer, and the insulator layer Sd corresponds to the third insulator layer.

In the pair of electrode patterns EC1a and EC1b, the electrode pattern EC1a corresponds to the first electrode pattern and the electrode pattern EC1b corresponds to the second electrode pattern. In addition, in the pair of electrode patterns EC1b and EC1c, the electrode pattern EC1b corresponds to the first electrode pattern and the electrode pattern EC1c corresponds to the second electrode pattern.

The conductor pattern CL1b is continuous along the conductor pattern CL1a, and the conductor pattern CL1c is continuous along the conductor pattern CL1b. A conductor pattern CL1b portion formed in the insulator layer Sb is connected to the conductor pattern CL1a over the entire length of extension of the conductor pattern CL1b in plan view. A conductor pattern CL1c portion formed in the insulator layer Sc is connected to the conductor pattern CL1b over the entire length of extension of the conductor pattern CL1c in plan view. The conductor patterns CL1a, CL1b, and CL1c define the inductor. In addition, the electrode patterns EC1a, EC1b, and EC1c and the insulator layers Sb and Sc define the capacitor.

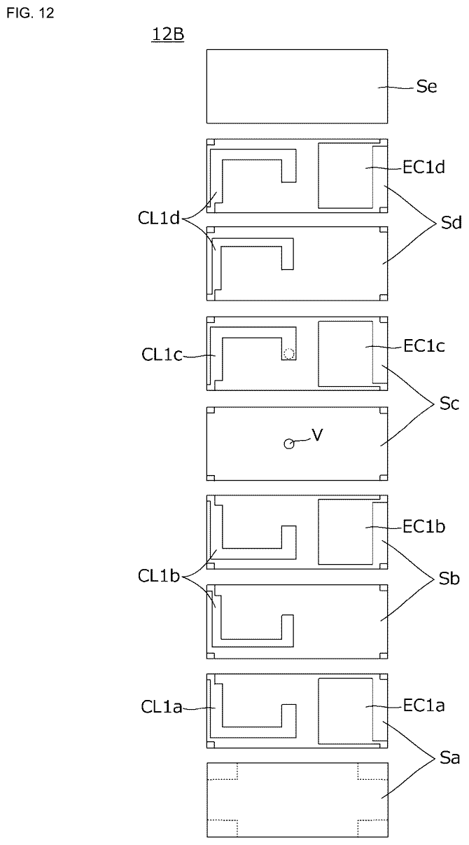

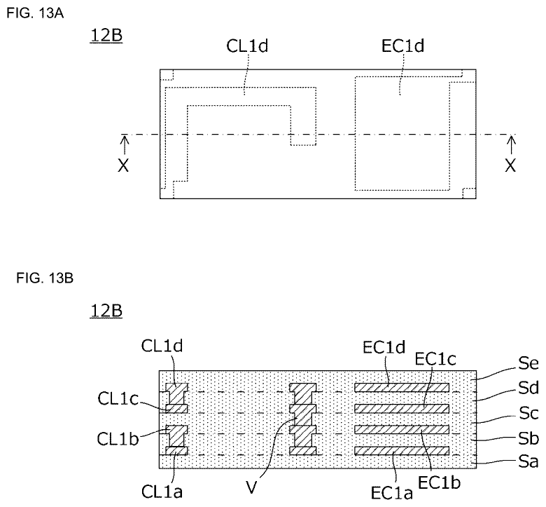

FIG. 12 illustrates exploded plan views of another electronic component 12B according to the second preferred embodiment. FIG. 13A is a plan view of the electronic component 12B, and FIG. 13B is a sectional view taken along line X-X in FIG. 13A.

This electronic component 12B includes the insulator layers Sa, Sb, Sc, Sd, and Se. A terminal electrode is formed on the lower surface of the insulator layer Sa. The conductor pattern CL1a and the electrode pattern EC1a are formed on the upper surface of the insulator layer Sa. The electrode pattern EC1b is formed on the upper surface of the insulator layer Sb. The conductor pattern CL1b is formed on the upper surface of the insulator layer Sb and in the insulator layer Sb. The conductor pattern CL1c and the electrode pattern EC1c are formed on the upper surface of the insulator layer Sc. A via conductor V that electrically connects an end portion of the conductor pattern CL1b and an end portion of the conductor pattern CL1c to each other is formed in the insulator layer Sc. An electrode pattern EC1d is formed on the upper surface of the insulator layer Sd. A conductor pattern CL1d is formed on the upper surface of the insulator layer Sd and in the insulator layer S. An insulator layer Se that covers the insulator layer Sd, the conductor pattern CL1d, and the electrode pattern EC1d is formed on the upper surface of the insulator layer Sd.

In the pair of conductor patterns CL1a and CL1b, the conductor pattern CL1a corresponds to the first conductor pattern, the conductor pattern CL1b corresponds to the second conductor pattern, the insulator layer Sa corresponds to the first insulator layer, the insulator layer Sb corresponds to the second insulator layer, and the insulator layer Sc corresponds to the third insulator layer. In addition, in the pair of conductor patterns CL1c and CL1d, the conductor pattern CL1c corresponds to the first conductor pattern, the conductor pattern CL1d corresponds to the second conductor pattern, the insulator layer Sc corresponds to the first insulator layer, the insulator layer Sd corresponds to the second insulator layer, and the insulator layer Se corresponds to the third insulator layer.

In the pair of electrode patterns EC1a and EC1b, the electrode pattern EC1a corresponds to the first electrode pattern and the electrode pattern EC1b corresponds to the second electrode pattern. In addition, in the pair of electrode patterns EC1c and EC1d, the electrode pattern EC1c corresponds to the first electrode pattern and the electrode pattern EC1d corresponds to the second electrode pattern.

The conductor pattern CL1b is continuous along the conductor pattern CL1a, and the conductor pattern CL1d is continuous along the conductor pattern CL1c. A conductor pattern CL1b portion formed in the insulator layer Sb is connected to the conductor pattern CL1a over the entire length of extension of the conductor pattern CL1b in plan view. A conductor pattern CL1d portion formed in the insulator layer Sd is connected to the conductor pattern CL1c over the entire length of extension of the conductor pattern CL1d in plan view. In addition, the conductor patterns CL1a, CL1b, CL1c, and CL1d define the inductor. In addition, the electrode patterns EC1a, EC1b, EC1c, and EC1d and the insulator layers Sb, Sc, and Sd define the capacitor.

### Third Preferred Embodiment

In a third preferred embodiment, an example of a filter module will be described.

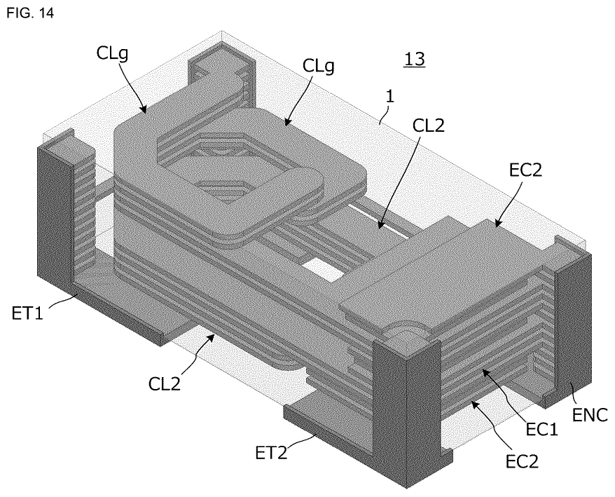

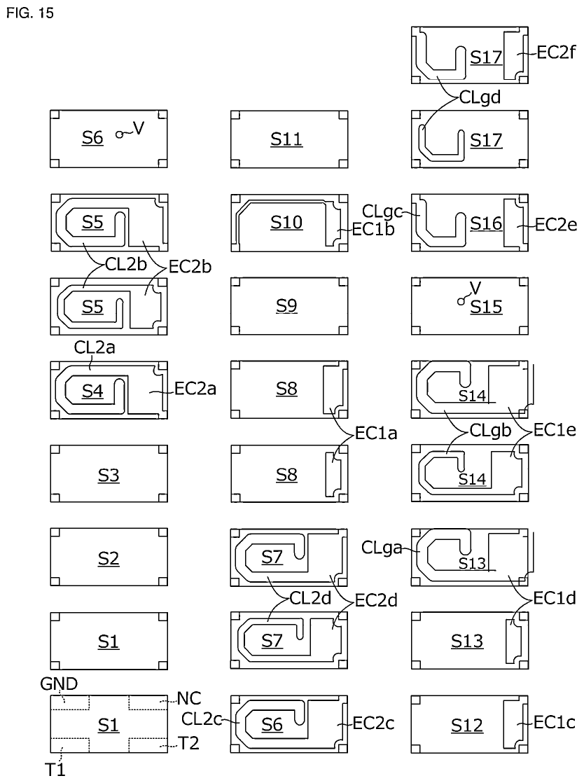

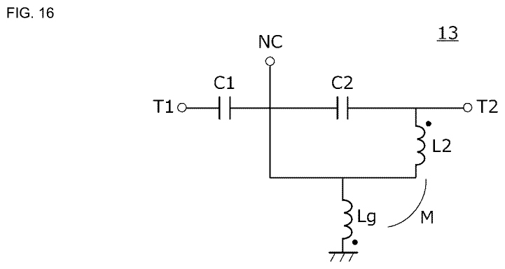

FIG. 14 is a perspective view of a filter module 13 according to the third preferred embodiment. FIG. 15 illustrates exploded plan views of insulator layers of the filter module 13 and conductor patterns formed on the insulator layers. FIG. 16 is a circuit diagram of the filter module 13.

As illustrated in FIG. 16, the filter module 13 includes the capacitors C1 and C2 and the inductors L2 and Lg. For example, the values of these elements are shown below.
C1: 0.56 pF
C2: 0.75 pF
Lg: 0.9 nH
L2: 1.2 nH
Coupling coefficient between inductors Lg and L2: 0.32

As illustrated in FIGS. 14 and 15, the filter module 13 includes a rectangular or substantially rectangular parallelepiped multilayer body 1 formed by laminating a plurality of rectangular insulator layers S1 to S17 together. A first terminal electrode ET1, a second terminal electrode ET2, a ground terminal electrode (terminal hidden in the background in FIG. 14), and a floating terminal electrode ENC for interlayer connection of internal electrodes, which are formed of, for example, plating, are formed on the outer surface of the multilayer body 1.

The inductor L2 includes conductor patterns CL2, which are formed in the multilayer body 1 including the plurality of insulator layers, and the inductor Lg includes conductor patterns CLg, which are formed in the multilayer body 1 including the plurality of insulator layers.

The capacitor C1 includes the electrode patterns EC1 facing each other in the lamination direction of the plurality of insulator layers, and the insulator layers sandwiched between these electrode patterns EC1. In addition, the capacitor C2 includes electrode patterns EC2 facing each other in the lamination direction of a plurality of insulator layers and the insulator layers sandwiched between these electrode patterns.

The conductor patterns CL2 include conductor patterns CL2a, CL2b, CL2c, and CL2d illustrated in FIG. 15. In addition, the conductor patterns CLg include conductor patterns CLga, CLgb, CLgc, and CLgd illustrated in FIG. 15. In addition, the electrode patterns EC1 include electrode patterns EC1a, EC1b, EC1c, EC1d, and EC1e illustrated in FIG. 15. Furthermore, the electrode patterns EC2 include electrode patterns EC2a, EC2b, EC2c, EC2d, EC2e, and EC2f illustrated in FIG. 15. The electrodes of the terminals T1, T2, GND, and NC are formed on the lower surface of the first insulator layer S1. Here, the electrodes of the terminals T1, T2, GND, and NC may be formed on the insulator layer S1 in advance or may be formed on the insulator layer S1 after the plurality of insulator layer are laminated together. In addition, an example in which the insulator layers S1 to S17 are laminated in sequence is shown in the present preferred embodiment. Conversely, starting with the insulator layer S17 on which the terminals T1, T2, GND, and NC are not formed, the insulator layers S16 to S1 may be laminated in this sequence.

The conductor pattern CL2b for forming the inductor has a shape that is continuous along the conductor pattern CL2a. A conductor pattern CL2b portion formed in the insulator layer S5 is connected to the conductor pattern CL2a over the entire length of extension of the conductor pattern CL2b in plan view. Similarly, the conductor pattern CL2d has a shape that is continuous along the conductor pattern CL2c. A conductor pattern CL2d portion formed in the insulator layer S7 is connected to the conductor pattern CL2c over the entire length of extension of the conductor pattern CL2d in plan view. The conductor pattern CLgd has a shape that is continuous along the conductor pattern CLgc. A conductor pattern CLgd portion formed in the insulator layer S17 is connected to the conductor pattern CLgc over the entire length of extension of the conductor pattern CLgd in plan view. The conductor pattern CLgb has a shape that is continuous along the conductor pattern CLga. A conductor pattern CLgb portion formed in the insulator layer S14 is connected to the conductor pattern CLga over the entire length of extension of the conductor pattern CLgb in plan view.

Ends of the conductor patterns CL2a and CL2b and ends of the conductor patterns CL2c and CL2d are connected to each other via the via conductor V. In addition, ends of the conductor patterns CLga and CLgb and ends of the conductor patterns CLgc and CLgd are connected to each other via the via conductor V.

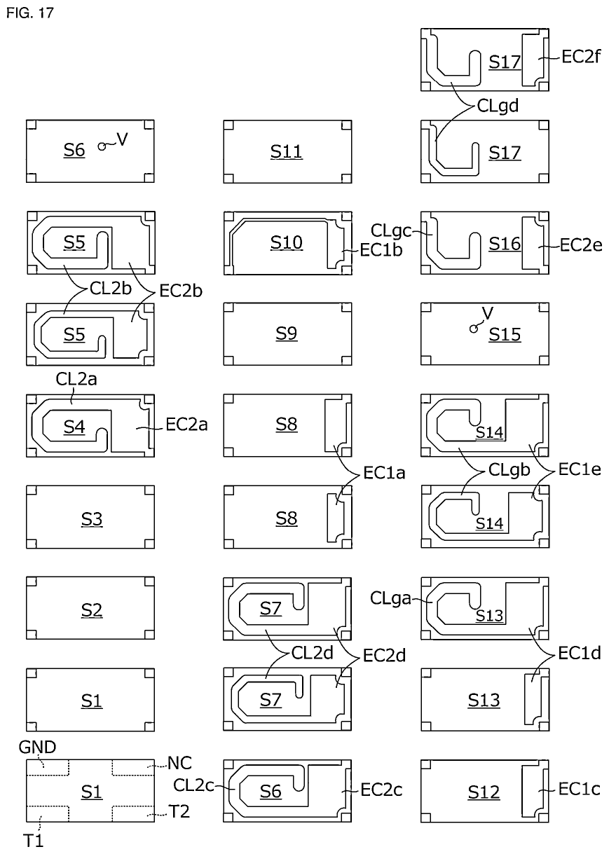

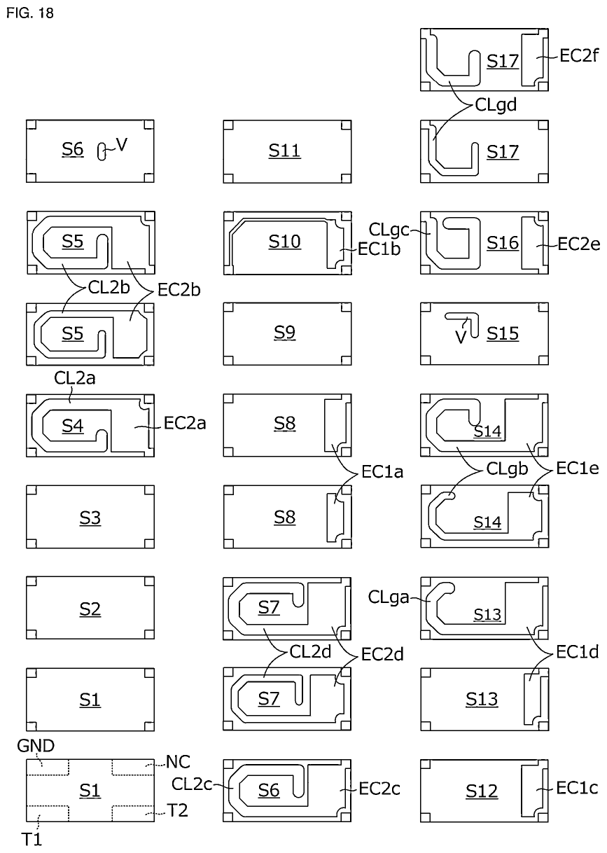

FIG. 17 and FIG. 18 are exploded plan views illustrating insulator layers of another filter module according to the third preferred embodiment and conductor patterns formed on the insulator layers.

The filter module illustrated in FIG. 17 differs from the filter module in FIG. 15 in the shapes of the conductor patterns CL2a and CL2b formed on the insulator layers S4 and S5, the shape of the conductor pattern CLgd formed on the insulator layer S17, and the shape of the electrode pattern EC1d formed on the insulator layer S13.

In the example illustrated in FIG. 17, the conductor pattern CL2a and the conductor patterns CL2b increase gradually in length in this order. This structure smooths changes in the conductor film thicknesses in the lamination direction of the conductor patterns CL2a and CL2b and alleviates the concentration of current flowing through the inductor L2.

In addition, in the example illustrated in FIG. 17, the end portion of the conductor pattern CLgd formed on the insulator layer S17 is connected to the conductor portion of the corner portion that is electrically connected to the terminal GND. This structure makes the conductor film thicknesses of the entire conductor patterns CLgc and CLgd including the end portions uniform and alleviates the concentration of current flowing through the inductor Lg.

In addition, in the example illustrated in FIG. 17, the end portion of the electrode pattern EC1d is connected to the conductor portion of the corner portion that is electrically connected to the terminal NC as in the electrode pattern EC1c. This structure smooths changes in the conductor film thicknesses in the lamination direction of the electrode patterns EC1c and EC1d that define the capacitor C1, alleviates the local concentration of current, and effectively improves the Q value of the inductor.

The filter module illustrated in FIG. 18 differs from the filter module in FIG. 17 in the shape of the via conductor V formed in the insulator layer S6, the shapes of the conductor patterns CL2c and CL2d formed on the insulator layers S6 and S7, the shapes of the conductor patterns CLga and CLgb formed on the insulator layers S13 and S14, the shape of the via conductor V formed in the insulator layer S15, and the shapes of the conductor patterns CLgc and CLgd formed on the insulator layers S16 and S17.

In the example illustrated in FIG. 18, the conductor pattern CL2c and the conductor pattern CL2d increase gradually in length in this order. Furthermore, the via conductor V that connects the conductor pattern CL2b and the conductor pattern CL2c to each other extends so as to connect the conductor pattern CL2b and the conductor pattern CL2c to each other along the layers. This structure smooths changes in the conductor film thicknesses in the lamination direction of the conductor patterns CL2b, CL2c, and CL2d and further alleviates the concentration of current flowing through the inductor L2.

In the example illustrated in FIG. 18, the conductor pattern CLga and the conductor pattern CLgb increase gradually in length in this order. Similarly, the conductor pattern CLgc and the conductor pattern CLgd decrease gradually in length in this order. Furthermore, the via conductor V that connects the conductor pattern CLgb and the conductor pattern CLgc extends so as to connect the conductor pattern CLgb and the conductor pattern CLgc along the layers. This structure smooths changes in the conductor film thicknesses in the lamination direction of the conductor patterns CLga, CLgb, CLgc, and CLgd and alleviates the concentration of current flowing through the inductor Lg.

### Fourth Preferred Embodiment

In a fourth preferred embodiment, an example of the junction structure in the lamination direction of the plurality of conductor patterns will be described.

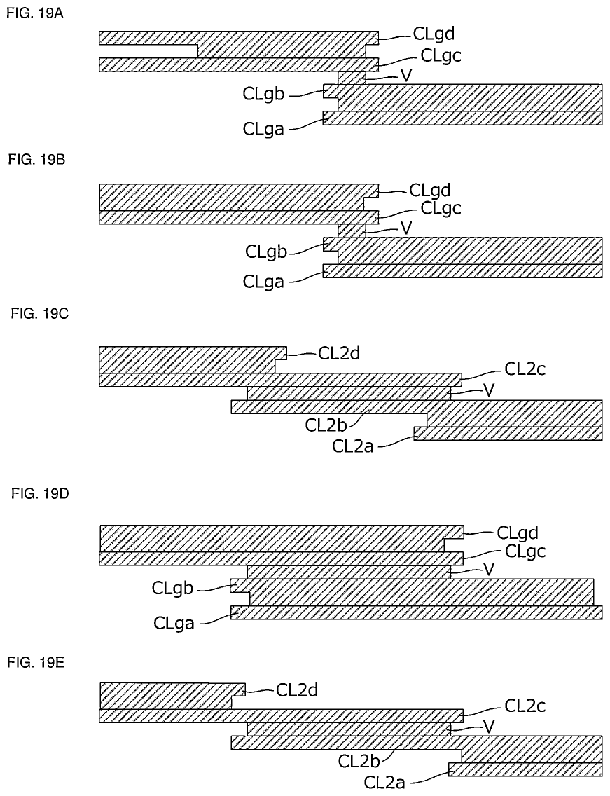

FIG. 19A is a diagram schematically illustrating the junction structure of the conductor patterns CLga, CLgb, CLgc, and CLgd for forming the inductor and the via conductor V as viewed in the direction orthogonal to the lamination direction. The insulator layers will not be illustrated. These conductor patterns and the via conductor correspond to the junction structure of the conductor patterns CLga and CLgb, the conductor patterns CLgc and CLgd, and the via conductor V in FIG. 15.

As illustrated in FIG. 19A, in the structure in which the conductor patterns are not partially connected in the lamination direction, the inductance of the inductor can be easily fine-tuned according to the length of the unconnected portion.

FIG. 19B is a sectional view of the conductor patterns CLga, CLgb, CLgc, and CLgd for forming the inductor and the via conductor V. The insulator layers will not be illustrated.

These conductor patterns and the via conductor correspond to the junction structure of the conductor patterns CLga and CLgb, the conductor patterns CLgc and CLgd, and the via conductor V in FIG. 17.

As illustrated in FIG. 19B, the equivalent series resistance of the inductor can be reduced and the inductor with a high Q value can be obtained by electrically connecting the conductor pattern CLgb to substantially the entire conductor pattern CLga and electrically connecting the conductor pattern CLgd to substantially the entire conductor pattern CLgc.

FIG. 19C is a sectional view of the conductor patterns CL2a, CL2b, CL2c, and CL2d for forming the inductor and the via conductor V. The insulator layers will not be illustrated. These conductor patterns and the via conductor correspond to the junction structure of the conductor patterns CL2a and CL2b, the conductor patterns CL2c and CL2d, and the via conductor V in FIG. 17.

As illustrated in FIG. 19C, changes in the number of layers of the conductor patterns in the lamination direction are smoothed, the local concentration of current is alleviated, and the Q value of the inductor can be effectively improved.

FIG. 19D is a sectional view of the conductor patterns CLga, CLgb, CLgc, and CLgd for forming the inductor and the via conductor V. The insulator layers will not be illustrated. These conductor patterns and the via conductor correspond to the junction structure of the conductor patterns CLga and CLgb, the conductor patterns CLgc and CLgd, and the via conductor V in FIG. 18.

The inductance of the inductor Lg can be easily fine-tuned by connecting the conductor patterns CLga and CLgb and the conductor patterns CLgc and CLgd over a long distance via the via conductor V as illustrated in FIG. 19D.

FIG. 19E is a sectional view of the conductor patterns CL2a, CL2b, CL2c, and CL2d for forming the inductor and the via conductor V. The insulator layers will not be illustrated. In this structure, compared with the example in FIG. 19C, the junction lengths of the conductor patterns CL2b and CL2c and the via conductor C are shorter and the number of conductor patterns laminated is less than three.

By preventing the number of conductor patterns laminated from increasing locally as illustrated in FIG. 19E, a structural defect such as a crack caused by a difference in firing shrinkage between the insulators and the conductor patterns during firing can be reduced or prevented.

### Fifth Preferred Embodiment

In a fifth preferred embodiment, an example of an electronic device including the filter module described above will be described.

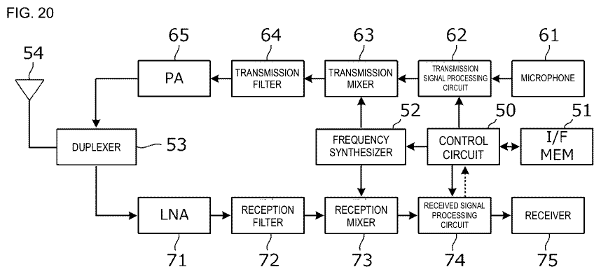

FIG. 20 is a block diagram illustrating the structure of an electronic device 201 according to the fifth preferred embodiment. This electronic device 201 is, for example, a smartphone or a mobile phone. This electronic device 201 includes a duplexer 53, an antenna 54, a control circuit 50, an interface and memory 51, and a frequency synthesizer 52. The transmission system includes a transmitter 61, a transmission signal processing circuit 62, a transmission mixer 63, a transmission filter 64, and a power amplifier 65. The reception system includes a low-noise amplifier 71, a reception filter 72, a reception mixer 73, a reception signal processing circuit 74, and a receiver 75. The transmission signal output from the power amplifier 65 is output to the antenna 54 via the duplexer 53. In addition, the signal received by the antenna 54 is amplified by the low-noise amplifier 71 via the duplexer 53. It should be noted that, in the case of data communication or the like instead of voice communication, the control circuit 50 processes the received signal.

A filter module according to a preferred embodiment of the present invention can be applied to the transmission filter 64 and the reception filter 72. In addition, a filter module according to a preferred embodiment of the present invention can be applied to the high-frequency filter of the duplexer 53.

In addition, when filters are provided at the front and rear of the power amplifier 65, at the front and rear of the low-noise amplifier 71, at the front and rear of the transmission mixer 63, and at the front and rear of the reception mixer 73 and the like, a filter module according to a preferred embodiment of the present invention can be applied to the filters.

Finally, the present invention is not limited to the preferred embodiments described above. Appropriate modifications and changes can be made by those skilled in the art. The scope of the present invention is indicated by the claims, not by the preferred embodiments described above. Furthermore, the scope of the present invention also includes modifications and changes of preferred embodiments within equivalents of the appended claims and within the appended claims.

For example, FIG. 1 illustrates an example in which the second conductor pattern CL12 that passes through the insulator layer S2 and is electrically connected continuously along the first conductor pattern CL11 is formed on the insulator layer S2, but the second conductor pattern CL12 may be discontinuously formed at a plurality of positions along the first conductor pattern CL11.

While preferred embodiments of the present invention have been described above, it is to be understood that variations and modifications will be apparent to those skilled in the art without departing from the scope and spirit of the present invention. The scope of the present invention, therefore, is to be determined solely by the following claims.

What is claimed is:

1. An electronic component comprising:
a first insulator layer including thereon a first conductor pattern to define an inductor and a first electrode pattern to define a capacitor; and
a second insulator layer including thereon a second conductor pattern to define the inductor and a second electrode pattern to define the capacitor; wherein
the first electrode pattern and the second electrode patter face each other across the second insulator layer to form the capacitor, and at least a portion of the second conductor pattern along the first conductor pattern is electrically connected to the first conductor pattern.

2. The electronic component according to claim 1, wherein the first conductor pattern and the first electrode pattern are made of a same material, and the second conductor pattern and the second electrode pattern are made of a same material.

3. The electronic component according to claim 1, wherein at least a portion of the second insulator layer includes a cavity immediately above the first conductor pattern, and the second electrode pattern is located in the cavity.

4. The electronic component according to claim 1, wherein the first conductor pattern has a loop shape or includes a portion of a loop and the second conductor pattern has a loop shape or includes a portion of a loop, and an inner edge of the loop of the first conductor pattern is aligned with an inner edge of the loop of the second conductor pattern in plan view in a lamination direction of the first conductor pattern and the second conductor pattern.

5. A method of manufacturing an electronic component, comprising:
simultaneously forming a first conductor pattern for forming an inductor and a first electrode pattern for forming a capacitor on a first insulator layer;
forming a second insulator layer on a surface of the first insulator layer on which the first conductor pattern is formed, the second insulator layer including a cavity above the first conductor pattern; and
forming a second conductor pattern for forming the inductor in the cavity and on the second insulator layer and forming a second electrode pattern for forming the capacitor at a position facing the first electrode pattern across the second insulator layer.

6. The method according to claim 5, wherein the first conductor pattern and the first electrode pattern are simultaneously formed by a first pattern forming step, and the second conductor pattern and the second electrode pattern are simultaneously formed by a second pattern forming step.

7. The method according to claim 5, wherein the first conductor pattern and the first electrode pattern are formed of a same material, and the second conductor pattern and the second electrode pattern are formed of a same material.

8. The method according to claim 5, wherein the first conductor pattern has a loop shape or includes a portion of a loop and the second conductor pattern has a loop shape or includes a portion of a loop, and an inner edge of the loop of the first conductor pattern is aligned with an inner edge of the loop of the second conductor pattern in plan view in a lamination direction of the first conductor pattern and the second conductor pattern.

9. A filter module comprising:
the electronic component according to claim 1; and
an inductor or a capacitor connected to the electronic component.

10. The filter module according to claim 9, wherein the first conductor pattern and the first electrode pattern are made of a same material, and the second conductor pattern and the second electrode pattern are made of a same material.

11. The filter module according to claim 9, wherein at least a portion of the second insulator layer includes a cavity immediately above the first conductor pattern, and the second electrode pattern is located in the cavity.

12. The filter module according to claim 9, wherein the first conductor pattern has a loop shape or includes a portion of a loop and the second conductor pattern has a loop shape or includes a portion of a loop, and an inner edge of the loop of the first conductor pattern is aligned with an inner edge of the loop of the second conductor pattern in plan view in a lamination direction of the first conductor pattern and the second conductor pattern.

13. An electronic device comprising:
the electronic component according to claim 1.

14. The electronic device according to claim 13, wherein the first conductor pattern and the first electrode pattern are made of a same material, and the second conductor pattern and the second electrode pattern are made of a same material.

15. The electronic device according to claim 13, wherein at least a portion of the second insulator layer includes a cavity immediately above the first conductor pattern, and the second electrode pattern is located in the cavity.

16. The electronic device according to claim 13, wherein the first conductor pattern has a loop shape or includes a portion of a loop and the second conductor pattern has a loop shape or includes a portion of a loop, and an inner edge of the loop of the first conductor pattern is aligned with an inner edge of the loop of the second conductor pattern in plan view in a lamination direction of the first conductor pattern and the second conductor pattern.

17. An electronic device comprising:
the filter module according to claim 9.

18. The electronic device according to claim 17, wherein the first conductor pattern and the first electrode pattern are made of a same material, and the second conductor pattern and the second electrode pattern are made of a same material.

19. The electronic device according to claim 17, wherein at least a portion of the second insulator layer includes a cavity immediately above the first conductor pattern, and the second electrode pattern is located in the cavity.

20. The electronic device according to claim 17, wherein the first conductor pattern has a loop shape or includes a portion of a loop and the second conductor pattern has a loop shape or includes a portion of a loop, and an inner edge of the loop of the first conductor pattern is aligned with an inner edge of the loop of the second conductor pattern in plan view in a lamination direction of the first conductor pattern and the second conductor pattern.
